(19) United States
(12) Patent Application Publication
(10) Pub. No.: US 2008/0002378 A1
(43) Pub. Date: Jan. 3, 2008

(54) Power conversion device frame packaging apparatus and methods

(76) Inventors: Steven Lee Willing, Encinitas, CA (US); Kent C. Carlson, Allentown, PA (US); Robert Campbell, Colorado Springs, CO (US); Alberto Avendano, Anaheim, CA (US)

Correspondence Address: CHARLES N. QUINN;FOX ROTHSCHILD LLP, 2000 MARKET STREET, 10TH FLOOR, PHILADELPHIA, PA, 19103, US

(21) Appl. No.: 11/820,476

(22) Filed: Jun. 18, 2007

Related U.S. Application Data
(63) Continuation of application No. 11/075,539, filed on Mar. 9, 2005, now abandoned.
(60) Provisional application No. 60/551,915, filed on Mar. 10, 2004.

(51) Int. Cl. H05K 5/00

(52) U.S. Cl. 361/752

(57) ABSTRACT

A plastic frame for converting a powered printed circuit board to an open frame power supply suitable for mounting on standoffs includes a ground plane that fits beneath the power supply combined with the solid plastic cover to electrically isolate the ground plane and a second printed circuit board providing the isolated ground plane with the powered printed circuit board matching standard power supply board and mounting dimensions.

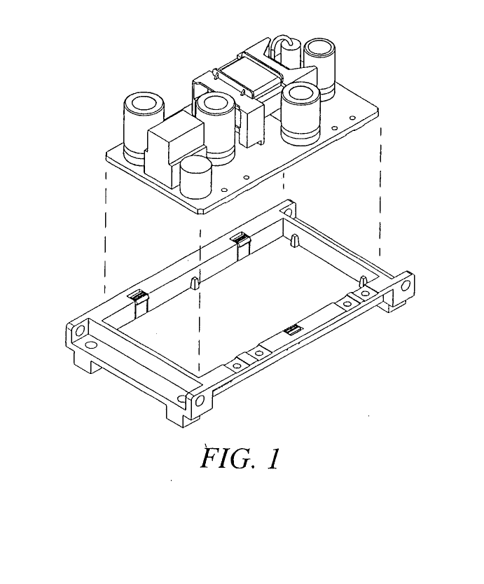

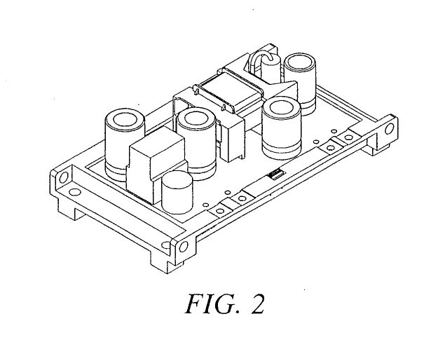

### CROSS-REFERENCE TO RELATED PATENT APPLICATIONS

This patent application claims the benefit, under the applicable provisions of 35 USC 119 and 120, of the priority of U.S. provisional patent application Ser. No. 60/551,915, entitled “Frame Packaging System for Power Conversion Devices, filed 10 Mar. 2004, the disclosure of which is hereby incorporated by reference in its entirety, and is a continuation of U.S. utility application Ser. No. 11/075,539, filed 9 Mar. 2005, the priority of which is also claimed.

### BACKGROUND OF THE INVENTION

Switch mode power supplies are widely used in a variety of applications to convert Alternating Current (AC) mains power to one or more electrically isolated Direct Current (DC) outputs. The technology used for switch mode designs has improved substantially over the past decade allowing for smaller and more efficient designs. As designs footprints have shrunk and as power conversion efficiency has improved many new packaging options have become feasible. As a consequence, power supply customers are demanding an ever increasing array of packaging options.

Typical packaging options include, but are not limited to the following.
Open Frame: A rectangular printed circuit board that contains the power supply circuit. The board typically has a mounting hole in each corner. Stand offs are use to mount the power supply inside the chassis of electrical equipment.
Cage Frame: This is a metal Faraday cage that fits over an open frame power supply. The cage is used to screen out electromagnetic interference generated by the power supply.
U-Channel: This is an open frame power supply mounted in a “U” shaped metal frame. This metal frame is usually solid except for mounting holes. In many cases the frame is used to provide an electrical ground plane beneath the power supply. It is also often used to provide heat sinking for the power supply.
Desk Top Adapter: This is a power supply packaged inside a plastic enclosure. The enclosure has an AC cable or connector on the input side and an DC cable or connector on the output side. This allows users to use the power supply external to the chassis of the equipment that it provides power for. A typical application is the external power supply for a notebook computer. By removing the power supply from the computer, the computer designer can create a smaller computer, can separate the computer from the heat and electromagnetic interference created by the power supply, and they can simplify re-design cycles since the AC to DC conversion device does not have to be included in the safety approval process for the computer.
Wall Mount: This is an external power supply designed for mounting directly on an AC outlet.
Module: This is a power supply packaged for mounting directly on a printed circuit board. It typically has metal posts designed to be soldered directly to a printed circuit board. This approach is often used for power converters that adjust from one DC voltage to one or more lower DC voltages. It is also used for small AC to DC converters.

In addition to the basic packaging styles described above, there are many other options available. Most of these relate to different ways to remove heat, connect to or from the power supply, or reduce electromagnetic interference.

The unfortunate consequence of a wider array of options is difficulty in maintaining suitable stock in the distribution channels and increased production costs. A key consequence of the variety of packaging options means that there are often multiple versions of the power supply circuit reproduced on different printed circuit boards. The key difference between these boards are related to the mounting of the board in the various packages. While this will tend to optimize the design of each particular power supply and package combination, it greatly adds to the complexity of a broad product line. This adds cost and complexity since each printed circuit board must be designed, tested, and approved by the appropriate safety agencies. It also adds distribution costs since redundant parts must be used to fully stock the distribution channel.

### DESCRIPTION OF THE DRAWING

The drawing submitted herewith is a photograph of a power conversion device frame package in accordance with and manifesting aspects of the invention in its currently preferred form.

### DETAILED DESCRIPTION OF THE PREFERRED EMBODIMENT OF THE INVENTION AND THE BEST MODE PRESENTLY CONTEMPLATED FOR THE PRACTICE OF THE INVENTION

This invention is for an improved packaging concept allowing standardized printed circuit boards to be re-used in a variety of packaging options. Rather then redesign the printed circuit board with different mounting characteristics for each packaging option, the invention utilizes a standardized printed circuit board and a snap-on plastic frame acting as an adapter to convert, combine and meet the mounting, interconnection, heat removal and electromagnetic characteristics of the overall power supply.

The invention focuses first on power supplies designed for desk top or wall mounted packages. These packages pose a significant design challenge since the plastic walls limit the removal of heat from the power supply. If a power supply can meet the thermal restrictions posed by a plastic case then it will typically perform even better as an open frame, semi-enclosed module or U-channel power supply.

Wall mount and desk top power supplies are typically designed for minimum size. A common mounting technique is to use edge card type connections between the power supply and the AC input connections. This is replicated for both input and output connections. A snap-on frame makes use of the same edge card design. Since other packaging techniques are generally less space constrained, the frame clips to the printed circuit board to provide mounting, interconnection, EMI protection and other features required by the end user of the power supply.

From a supply chain management point of view this increases flexibility of the product. A single printed circuit board can be packaged in many different ways. The printed circuit board can be manufactured in larger volumes, which lowers costs. Likewise, by standardizing the printed circuit board dimensions the frames can be used with several different power supply boards. This flexibility limits the inventory costs in the channel since it modularizes the product into components that can be stocked and easily assembled to meet demands of individual customers.

1) A plastic frame that converts the power printed circuit board to an open frame power supply suitable for mounting on stand-offs, comprising:
a) versions of this frame with various options to attach input and output connectors;
b) versions with solid plastic bottom to provide electrical isolation beneath the power supply;
c) a ground plane that fits beneath the power supply, combined with a solid plastic cover to electrically isolate the ground plane;
d) a second printed circuit board can also be used to provide the isolated ground plane. The frame could house the power printed circuit board and the ground plane printed circuit board and provide electrical connections between the two printed circuit boards;
e) versions that adapt the dimensions of the power printed circuit board to match standard power supply board or mounting dimensions;
f) frame versions that include provisions for an optional light emitting diode to indicate a selected parameter;
g) versions that would allow easy attachment of a Faraday cage;
h) versions of the frame that use edge card techniques to make electrical connections;
i) versions of the frame that use soldered or connector wire to make electrical connections to the Power printed circuit board;
j) versions of the frame that do not make electrical connections to the Power printed circuit board providing mechanical support;
k) versions of the frame with grooves, screw holes or other attachment methods to allow supports that enable perpendicular mounting of the power printed circuit board, by turning the power supply sideways this can help make more efficient use of the space inside of a chassis.

2) The frame of claim 1 further comprising:
a) corresponding desktop and wall-mounted power supply packages that use the same printed circuit board.

3) The frame of claim 1 further comprising:
a) versions of the frames with electrical connections designed for soldering to a larger printed circuit board, converting the power supply to a module.

4) The frame of claim 1 further comprising:
a) clips enabling mounting in a standard U-channel.

5) The frame of claim 1 wherein of the packages are applied to battery chargers, AC-AC converters and DC-DC converters.

6) The frame of claim 1 wherein
a) the frames will hold more then one power printed circuit board;
b) a bulk AC-DC printed circuit board used for initial power conversion and isolation;
c) a second board with DC-DC converters could be added to create distinct DC outputs;
d) a group of AC to single output DC power supplies giving several different DC outputs;
e) holding several different non-isolated DC-DC converters.
